(19) United States
(12) Patent Application Publication
(10) Pub. No.: US 2022/0199153 A1
(43) Pub. Date: Jun. 23, 2022

(54) SEMICONDUCTOR DEVICE

(71) Applicant: RENESAS ELECTRONICS CORPORATION, Tokyo (JP)

(72) Inventor: Shunya NAGATA, Tokyo (JP)

(21) Appl. No.: 17/548,989

(22) Filed: Dec. 13, 2021

(30) Foreign Application Priority Data
Dec. 22, 2020 (JP) 2020-212079

(51) Int. Cl. G11C 11/419; G11C 11/412; H01L 27/11

(52) U.S. Cl. CPC G11C 11/419; H01L 27/1116; H01L 27/1104; G11C 11/412

(57) ABSTRACT

The control circuit of the semiconductor device initializes a plurality of memory cells. The method is that when the reset signal is at a high level, the control circuit turns off the first transistor, selects multiple word lines, turns off the precharge circuit, turns on the write column switch, and turns off the read column switch. Then, the control circuit initializes a plurality of memory cells by setting the first bit line to the low level and the second bit line to the high level by the writing circuit.

### CROSS-REFERENCE TO RELATED APPLICATIONS

The disclosure of Japanese Patent Application No. 2020-212079 filed on Dec. 22, 2020 including the specification, drawings and abstract is incorporated herein by reference in its entirety.

### BACKGROUND

The present disclosure relates to a semiconductor device, and more particularly, the present disclosure relates to a technique useful for a semiconductor device including a static random access memory (SRAM).

In many cases, a static random access memory (SRAM) is incorporated as a memory device for holding data in a semiconductor device such as a data processing device. If critical data is stored in this SRAM, countermeasures must be taken from the tamper-proof point of view. There is a need for techniques to instantaneously erase or initialize critical data stored in a SRAM so that the content of critical data stored in it is not read by a malicious user.

There are disclosed techniques listed below.
[Patent Document 1] U.S. Patent Application Publication No. 2001/0046173
[Patent Document 2] U.S. Patent Application Publication No. 2006/0023521
[Patent Document 3] US Patent Application Publication No. 2014/0293679
[Non-patent Document 1] Kevin Self, APPLICATION NOTE 2033, SRAM-Based Microcontroller Optimizes Security,[online], Jun. 27, 2003, [Searched: Nov. 25, 2020], URL:https://pdfserv.maximintegrated.com/en/an/AN2033.pdf

### SUMMARY

It is an object of the present disclosure to provide a technique capable of initializing data of a memory cell at a relatively high speed while suppressing an increase in area.

Other objects and novel features will become apparent from the description of this specification and the accompanying drawings.

An outline of representative ones of the present disclosure will be briefly described below.

A semiconductor device according to an embodiment includes a plurality of word lines, a plurality of pairs of first bit lines and second bit lines, a plurality of memory cells connected to a plurality of word lines and a plurality of pairs of first bit lines and a second bit line so as to be connected to one word line and a pair of first bit lines and a second bit line, a first transistor provided between the plurality of memory cells and a power supply potential, a plurality of word line drivers connected to the plurality of word lines, a write column switch connected to each of the plurality of pairs of first bit lines and second bit lines, a read column switch connected to each of the plurality of pairs of first bit lines and second bit lines, a precharge circuit connected to each of the plurality of pairs of first bit lines and second bit lines, a write circuit connected to each write column switch, and a control circuit receiving a reset signal.

The control circuit initializes the plurality of memory cells by setting the first bit line to a low level by the write circuit and the second bit line to a high level by setting the first transistor to an off state, a plurality of word lines to a selected state, a precharge circuit to an off state, a column switch for writing to an on state, and a column switch for reading to an off state based on the fact that the reset signal is set to a high level.

According to the semiconductor device of the above embodiment, the data of the memory cell can be initialized at a relatively high speed while suppressing an increase in the area.

### BRIEF DESCRIPTION OF THE DRAWINGS

FIG. 1 is a diagram illustrating an overall configuration of a memory device according to an embodiment.

FIG. 2 is a diagram illustrating a memory cell portion of the memory device of FIG. 1.

FIG. 3 is a diagram illustrating an input/output unit of the memory device of FIG. 1.

FIG. 4 is a diagram illustrating a word driver unit of the memory device of FIG. 1.

FIG. 5 is a diagram illustrating a control unit of the memory device of FIG. 1.

FIG. 6 is a timing chart when the reset signal is turned on in the normal operation state.

FIG. 7 is a timing chart when the reset signal is turned on in the standby state.

### DETAILED DESCRIPTION

Those Embodiments will be described below with reference to the drawings. However, in the following description, the same components are denoted by the same reference numerals, and a repetitive description thereof may be omitted. It should be noted that the drawings may be represented schematically in comparison with actual embodiments for the sake of clarity of explanation, but are merely an example and do not limit the interpretation of the present invention.

### Embodiments

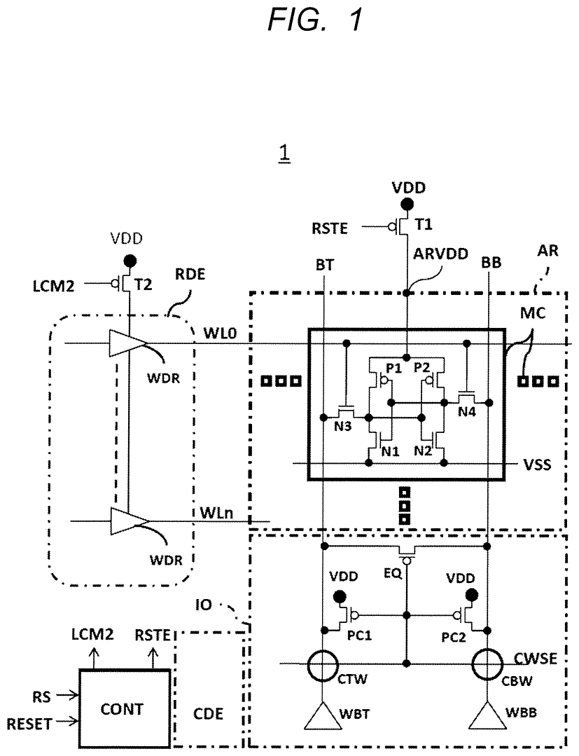

FIG. 1 illustrates the overall configuration of a static random access memory (hereinafter referred to as a SRAM) 1, which is a memory device. SRAM1 is a memory device for holding data built in a semiconductor device such as a data processing device. A central processing unit CPU, a SRAM1, other peripheral devices, and the like are built in the semiconductor chip on which the data processing device is formed.

SRAM1 includes a memory cell array unit AR, a word line decoder unit (also referred to as a row decoder unit) RDE, an input/output unit IO, a control unit (also referred to as a control circuit) CONT, a bit line decoder unit (also referred to as a column decoder) CDE, and the like.

(Memory Array Part AR)

The memory array unit AR includes a plurality of memory cells MC arranged in a matrix, a plurality of word lines, and a plurality of pairs of first bit line BT and second bit line BB. Each memory cell is connected to a pair of first bit line BT and second bit line BB, one word line WL (in FIG. 1, described as a WL0). Each memory cell includes two transfer transistors N3 and N4 composed of N-channel type MOS field effect transistors, two load transistors P1 and P2 composed of P-channel type MOS field effect transistors, and two drive transistors N1 and N2 composed of N-channel type MOS field effect transistors. The source-drain path of the load transistor P1 and the source-drain path of the drive transistor N1 are connected in series between the memory array power supply potential ARVDD and the ground potential VSS. The source-drain path of the load transistor P2 and the source-drain path of the drive transistor N2 are connected in series between the memory cell power supply potential ARVDD and the ground potential VSS.

The gate of the gate and the driving transistor N1 of the load transistor P1 is connected to constitute a common gate, the drain of the drain and the driving transistor N2 of the load transistor P2 is connected to constitute a common drain, the common gate of the load transistor P1 and the driving transistor N1 is connected to the common drain of the load transistor P2 and the driving transistor N2. Similarly, the gate of the gate and the driving transistor N2 of the load transistor P2 is connected to constitute a common gate, the drain of the drain and the driving transistor N1 of the load transistor P1 is connected to constitute a common drain, the common gate of the load transistor P2 and the driving transistor N2 is connected to the common drain of the load transistor P1 and the driving transistor N1.

Source drain path of the transfer transistor N3 is connected between the common drain of the first bit line BT and the load transistor P1 and the driving transistor N1. The gate of the transfer transistor N3 is connected to the word-line WL0. Source drain path of the transfer transistor N4 is connected between the common drain of the second bit line BB and the load transistor P2 and the drive transistor N2. The gate of the transfer transistor N4 is connected to the word line WL.

When the first bit line BT is set to the write data of the high level “1” and the second bit line BB is set to the write data of the low level “0” and the word line WL is set to the selected level of the high level, the transfer transistors N3 and N4 are turned on and the data of the high level “1” is stored in the memory cell MC. On the other hand, when the first bit line BT is set to the write data of the low level “0” and the second bit line BB is set to the write data of the high level “1” and the word line WL is set to the selected level of the high level, the transfer transistors N3 and N4 are turned on and the data of the low level “0” is stored in the memory cell MC. In this specification, a state in which the memory cell MC stores data of low level “0” is referred to as a low-level data write state or an initialization state of the memory cell MC. Of course, the state in which the memory cell MC stores high-level “1” data may be defined as the initialization state of the memory cell MC.

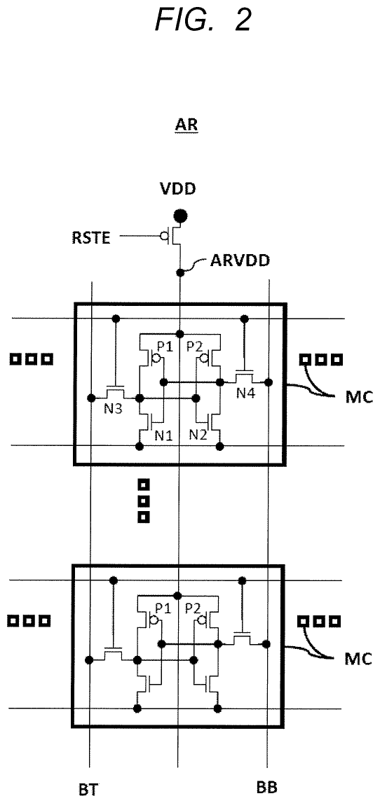

As shown in FIGS. 1 and 2, between the power supply potential VDD and the memory array power supply potential AR DD, the source-drain path of the transistor (first transistor) T1 composed of a P-channel MOS field-effect transistor is connected, the gate of the transistor T1, the control unit CONT, the control signal RSTE is set to a high level “H” at the time of reset It is configured to be supplied. As shown in FIG. 2, in a plurality of each memory cell cells MC constituting one column connected between the first bit line BT and the second bit line BB, the sources of the load transistors P1 and P2 of the memory cells MC are connected to the power supply potential VDD via the source-drain path of the transistor T1. Other columns (not shown) are similarly configured. As a result, since the transistor Tl is turned off at the time of reset, the memory holding ability of all the memory cells MC in the memory array AR is disabled, so that the data stored in each memory cell MC can be easily initialized. In addition, all memory cells MC in the memory array AR can be initialized in a single operation.

(Word Line Decoder RDE)

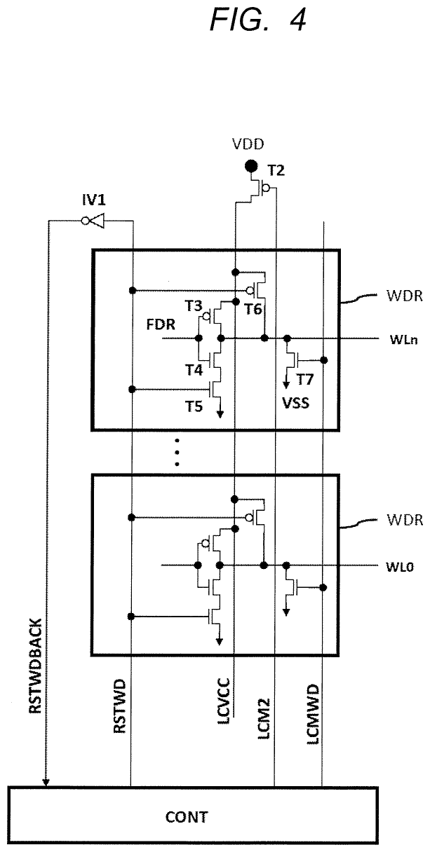

The word line decoder RDE includes a row decoder circuit (not shown) that decodes the address signal and selects one word line, and a plurality of word line drivers WDR connected to receive the output of the row decoder circuit. The plurality of word line drivers WDRs are connected to the plurality of word lines WL0-WLn, respectively, and drive selected word lines. As shown in FIGS. 1 and 4, the source-drain path of the transistor (second transistor) T2 composed of the P-channel MOS field-effect transistor is connected between the VDD-side terminal and the power supply potential VDD of the final driver of the plurality of word line drivers WDR, and the gate of the transistor T2 is configured to be supplied with a control signal LCM2 that is set to a low level “L” at the time of resetting from the control unit CONT. The plurality of word line drivers WDRs are configured to select all the word lines WL0-WLn at the time of resetting. Transistor T2 is provided to reduce the rush current generated when the all word-line WL0-WLn is simultaneously started up to a selected state, and is a current limiting PMOS transistor having a role of limiting the current amount of the rush current.

As shown in FIG. 4, the word line driver WDR has a final driver FDR composed of a P-channel MOS field-effect transistor T3 and an N-channel MOS field-effect transistor T4, and an N-channel MOS field-effect transistor T5 having a source-drain path connected between the source of the N-channel MOS field-effect transistor T4 and the ground potential VSS. The input to the final driver FDR is connected to receive the output from the row decoder circuit. The word line driver WDR further includes a P-channel MOS field effect transistor T6 having a source-drain path connected between the word line WLn connected to the output of the final driver FDR and the source of the transistor T2, and an N-channel MOS field effect transistor T7 having a source-drain path connected between the word line WLn and the ground potential VSS. The gates of the transistors T5 and T6 are connected to the wiring so as to receive the control signal RSTWD, and the gates of the transistors T7 are connected to the wiring so as to receive the control signal LCMWD. Control signal RSTWD is a control signal RSTWDBACK by the inverter IV1 is returned to the control unit CONT. After the word line falls, the control signal RSTWD is inverted by the inverter IV1 to generate a control signal RSTWDBACK in order to start the precharging of the bit, lines BT and BB, and the control signal is returned to the control section CONT. In the control unit CONT, the logic between the control signal RSTWDBACK and the control signal RETE. In other words, when the reset signal is released (when the reset signal transitions from the high level to the low level), the signal at the far end of the word line lowering signal is fed back to the control unit CONT, and the precharging of the bit lines BT and BB is started after all the word line falling is completed. Thus, since it is possible to prevent the extra through power due to the overlap between the active period of the high level of the word line WL and the precharge period of the bit lines BT and BB, it is possible to reduce the operating current during the reset operation.

(I/O Unit IO)

As shown in FIG. 1, the input-output unit IO has a pre-charge circuit including an equalization transistor EQ composed of a P-channel MOS field-effect transistor having a source-drain path connected between the bit lines BT and BB, a pre-charge transistor PC1 composed of a P-channel MOS field-effect transistor having a source-drain path connected to the power supply potential VDD and the bit line BT, and a pre-charge transistor PC2 composed of a P-channel MOS field-effect transistor having a source-drain path connected to the power supply potential VDD and the bit line BB. Transistor EQs, the gates of PC1, PC2 are commonly connected and configured to receive control-signal CWSE. Transistor EQ, PC1, PC2 is turned off by the control signal CWSE of the high level “H”, by the control signal CWSE of the low level “L”, is turned on. At the time of resetting, the transistor EQ, PC1, PC2, by the control signal CWSE of the high level “H”, is turned off by the control signal CWSE of the high level “H”. The control signal CWSE can also be referred to as a column light select signal.

The input/output unit IO also includes a first write circuit (also referred to as a write buffer) WBT for supplying write data to the bit line BT, and a second write circuit (also referred to as a write buffer) WBB for supplying write data to the bit line BB. At reset, the write circuit WBT supplies low-level “L” write data to the bit line BT, and the write circuit WBB supplies high-level “H” write data to the bit line BB. Therefore, at the time of reset, all the bit lines BT of all the columns are set to the potential level of the low level “L”, and all the bit lines BB of all the columns are set to the potential level of the high level “H”.

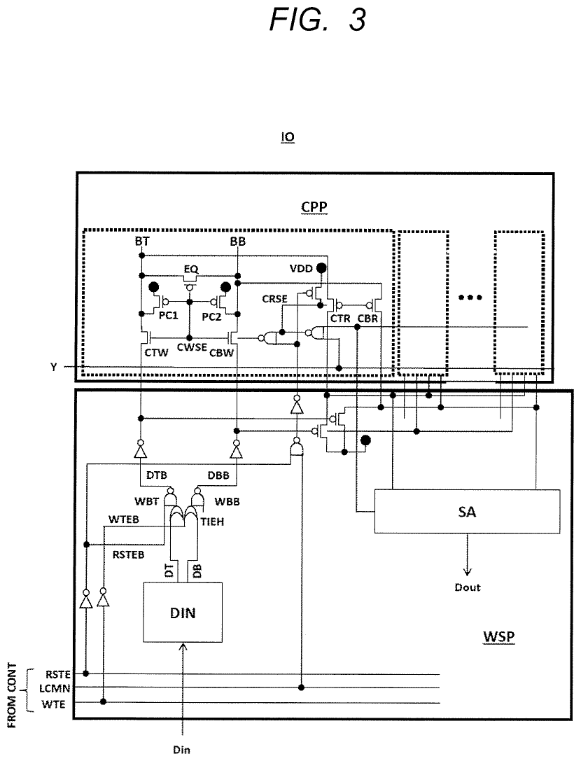

The input/output unit IO also includes first and second column switches CTW and CBW for writing. The column switch CTW has a source drain path connected between the output of the write circuit WBT and the bit line BT. The column switch CBW has a source drain path connected between the output of the write circuit WBB and the bit line BT. The gates of the column switches CTW, CBW are supplied with control signal CWSE. The input/output unit IO further includes first and second column switches CTR and CBR for reading (see FIG. 3 The column switch CTR has a source drain path connected between the bit line BT and the input of the sense amplifier SA. The column switch CBR has a source drain path connected between the bitline BT and the input of the sense amplifier SA. At the time of reset, the write column switches CTW and CBW of all the columns are configured to be turned on, and the read column switches CTR and CBR of all the columns are configured to be turned off.

That is, at the time of reset, the transistor T1 is turned off, all the word lines WL are selected, and the transfer transistors N3 and N4 of all the memory cells MC are turned on. Then, the column switches CTW and CBW for writing all columns are turned on, the write circuit WBT supplies low-level “L” write data to the bit line BT, and the write circuit WBB supplies high-level “H” write data to the bit line BB. Thus, the stored data of all the memory cells is quickly initialized.

FIG. 3 shows a detailed circuit configuration of the input/output unit IO. The input/output unit IO includes a column selector and a precharge unit CPP, and a write buffer and a sense amplifier unit WSP. The column selector and precharge section CPP includes a transistor EQ as a precharge circuit, a PC1, PC2, column switches CTW, CBW for and column switches CTR, CBR for reading, as described in FIG. 1. The control CRSE is fed to the gates of the column-switched CTRs and CBRs for readout. The control signal CRSE can also be referred to as a column read select signal. At the time of resetting, the control signals CRSE of all the columns are set to the high level “H”, and the control signals CRSE of all the columns are set to the low level “L”.

The column selector and precharge unit CPP are configured to receive a selection signal Y from the bit line decoder unit CDE at the time of normal writing and at the time of normal reading. The control signal CWSE is set to a high level “H” based on the normal write mode and the selection signal Y of the selection level “H”. Further, the control signal CRSE based on the selection signal Y of the normal read mode and the selection level “H” is a high level “H”.

The write buffer/sense amplifier unit WSP includes a data input circuit DIN to which input data Din to be written to a memory cell selected at the time of normal writing is supplied, and a sense amplifier SA which detects data stored in the memory cell selected at the time of normal reading and outputs the detected data as read data Dout. The data input circuit DIN generates write data DT to the bit line BT and write data DB to the bit line BB based on the input data Din during normal writing. The data DT and BT are supplied to the bit lines BT and BB via the write column switches CTW and CBW which are turned on. DTB and DBE indicate inverted signals of the data DT and BT.

As shown in FIG. 3, the write buffer and the sense amplifier unit WSP is adapted to receive the control signal RSTE, LCMN, WTE from the control unit CONT. The control signal RSTE is a signal that is set to a high level “H” at resetting. The control signal WTE is a signal that is set to a high level “H” during normal writing. The control signal RSTEB indicates the inverted signal of the control signal RSTE. The control signal WTEB indicates the inverted signal of the control signal WTE. Control signal TIEH, in the combined circuit of NAND circuit and the OR circuit provided on the output side of the data input circuit DIN, a dummy signal for maintaining the contrastability with the control signal RSTEB. At the time of resetting, when the control signal RSTE is a high level “H” (control signal RSTEB is low level “L”), the inverted data signal DTB is a high level “H”, the inverted data signal DBB is a low level “L”. Thus, at the time of reset, the bit line BT is set to the low level “L” and the bit line BB is set to the high level “H”, so that the memory cell MC can be set to the initialized state.

(Control CONT)

At the time of resetting, the control unit CONT shown in FIG. 1 controls the internal one-shot clock to fall to turn off the write operation and the read operation, and to turn off the column selection. In addition, the control unit CONT waits for the rise of the word line WL when the word line WL leaves the reset state (at the time of reset cancellation or at the time of reset mode cancellation) and then controls the bit lines BT and BB to start precharging.

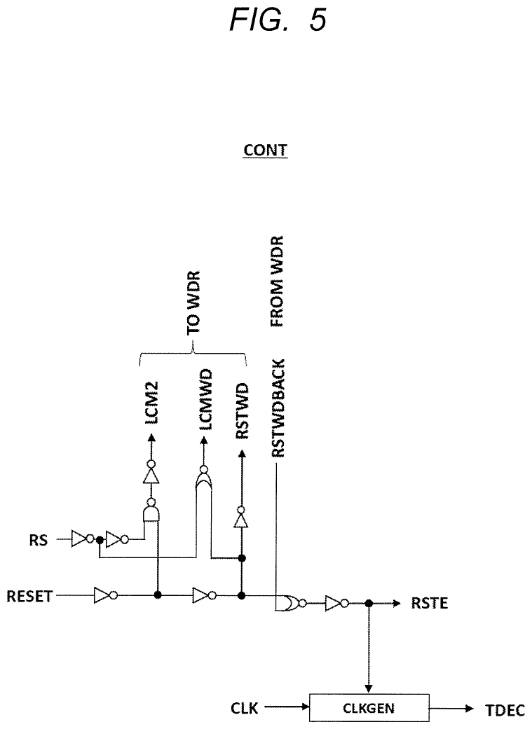

FIG. 5 is a detailed circuit configuration of the control unit CONT. Control unit CONT includes a standby signal RS, a reset signal RESET, is configured to receive a clock signal CLK. When the standby signal RS is set to the high level “H”, SRAM1 of the standby signal RS is set to the standby state. When the standby signal RS is set to the low level “L”, SRAM1 is set to the normal operation mode. Normal operating modes include read and write modes. When the reset signal RESET is set to high level “H”, SRAM1 is set to the reset state. When SRAM1 is reset, all memory cells MC in SRAM1 are initialized.

The control unit CONT is constituted by a plurality of logical circuits shown in FIG. 5. The control unit CONT generates a control signal LCM2, LCMWD, RSTWD from the standby signal RS and the reset signal RESET and supplies it to the word line driver WDR. Further, the control unit CONT is supplied with the control signal RSTWDBACK from the word line driver WDR. The control unit CONT, based on the reset signal RESET and the control signal RSTWDBACK, generates a control signal RSTE. Control signal RSTE, the bit lines BT, BB, a control signal for applying a potential setting of the memory cell data initialization, and is used as a control signal for cutting off the VDD-side power supply of the memory cell (to turn off the transistor T1). The control signal RSTWDBACK is a return signal of the falling signal at the far end of the word line for starting the re-charging of the bit line after the word line falls when the reset is released. The control unit CONT also includes an internal clock generation circuit CLKGEN for writing and reading, the internal clock generation circuit CLKGEN receives the clock signal CLK, generates a control signal TDEC such as an internal one-shot clock. Internal clock generator CLKGEN is adapted to receive a control signal RSTE, at the time of resetting, is configured to stop the generation of the internal clock for write and read operations (internal one-shot clock).

(Timing Chart)

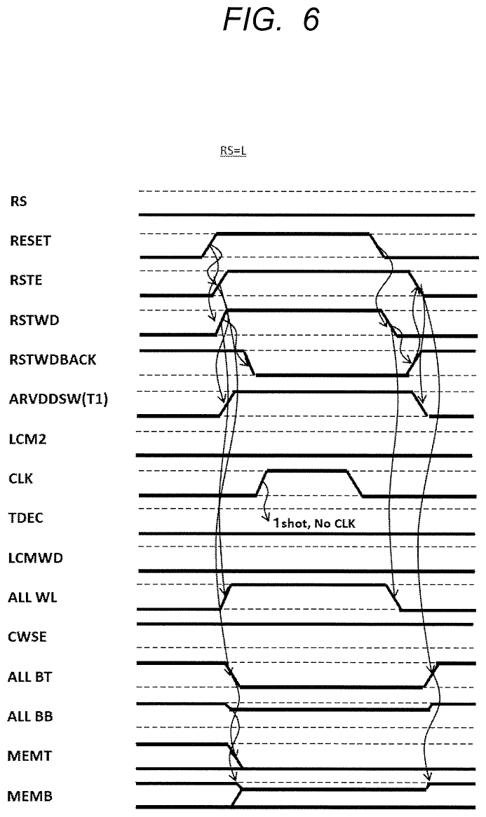

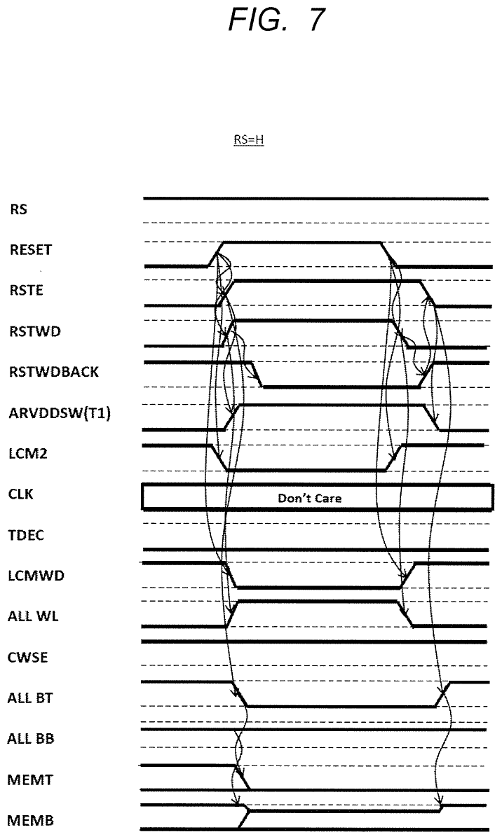

FIG. 6 is a timing chart when the normal operation state that the standby signal RS is the low level “L”. And it is when the reset signal RESET changes from the low level “L” to the high level “H” and the SRAM 1 is in the reset state. FIG. 7 is a timing chart when the standby state that the standby signal RS is at the high level “H”. And it is when the reset signal RESET is changed from the low level “L” to the high level “H” and the SRAM 1 is in the reset state. In FIGS. 6 and 7, the clock signal CLK, the waveform of the control signal LCM2 and LCMWD are different respectively.

In FIGS. 6 and 7, the control signal RSTE transitions to the high level “H” based on the high level “H” of the reset signal RESET. Based on the transition of the control signal RSTE to the high level “H”, the transistor T1 is turned off, all the word lines are set to the selection level “H”, all the bit lines BT are set to the low level, and all the bit lines BB are set to the high level. Thus, the storage node MEMT of the memory cell MC is set to a low level, the storage node MEMB of the memory cell MC is set to a high level, and all the memory cells MC are set to an initialized state. The storage node MEMT is a node of the common drains of the transistor P1 and the transistor N1 of the memory cell MC. The storage node MEMB is a common-drain node of the transistor P2 and the common-drain node of the transistor N2 of the memory cell MC.

In FIGS. 6 and 7, when the state signal RESET is set from a high level “H” to a low level “L”, the transistor T1 is turned on, all the word lines are non-selected level “L”, and all the bit lines BB, which are surrounded by all the bit lines BT, are set to a pre-charge level such as a high level. The memory cell MC maintains an initialization state.

According to the embodiment, one or more of the following effects can be obtained.

1) The VDD side of the memory cell array AR is connected to the VDD via switch T1. At the time of reset, and a circuit. configuration for turning off the switch T1. The off state of switch T1 disables the memory retention capability of all memory cells and can be initialized at once. This can shorten the initialization time of all memory cells without increasing the area.

2) The circuit configuration is such that all word lines are simultaneously selected at the time of reset. The initialization time of all memory cells can be shortened because the word lines can be started at the same time and the memory cells can be initialized at the same time.

3) At the time of resetting, using a normal data writing circuit (WBT, WBB) in SRM, all the bit lines BT, BB, a circuit configuration for applying a low level and a high level for initialization. Since the data write circuit (WBT, WBB) to the normal memory cell is diverted, there is no increase in area.

4) By the reset signal, a circuit configuration in which the one-shot clock of the internal clock generation circuit CLKGEN for Write/Read is turned off. Since the internal-clock generating circuit CLKGEN is turned off, even if the reset signal RESET changes to the high level at any time, the internal-clock generating circuit can immediately shift to the initialization operation of all the memory cells, and therefore, all the memory cells can be initialized in a short time regardless of SRAM operation modes.

5) The source of PMOS (T3) of the word-line startup Inverter (final driver FDR) is connected to the power supply potential VDD via the current limiting MOS (T2). With the current limiting PMOS (T2), the peak current of the word line driver WDR at reset can be reduced to limit and suppress the rush current caused by the simultaneous rising of all word lines.

6) When the reset mode is released, the word line falls first, and then the precharge of the bit lines BT and BB is generated by the transistors EQ, PC1 and PC2. Since it is possible to prevent the extra through power due to the overlap between the active period of the high level of the word line WL and the precharge period of the bit lines BT, BB, the operating current during the reset operation can be reduced.

While the invention made by the present inventor has been specifically described above based on the Embodiment, the present invention is not limited to the above-described embodiment and Embodiment, and it is needless to say that the present invention can be variously modified.

What is claimed is:

1. A semiconductor device comprising:
a plurality of word lines;
plurality of pairs of first bit line and second bit line;
a plurality of memory cells connected to the plurality of word lines and the plurality of pairs of first bit line and the second bit line;
a first transistor provided between the plurality of memory cells and the power supply potential line;
a plurality of word line drivers connected to the plurality of word lines;
a write column switch connected to each of the plurality of pairs of first and second bit lines;
a read column switch connected to each of the plurality of pairs of first and second bit lines;
a precharge circuit connected to each of the plurality of pairs of first and second bit lines;
a write circuit connected to each write column switch; and
a control circuit receiving a reset signal,
wherein the control circuit sets, based on the reset signal becoming high level, the first transistor in the off state, the plurality of word lines in the selected state, the precharge circuit in the off state, the write column switch in the on state and the read column switch in the off state,
and wherein the control circuit initializes the plurality of memory cells by controlling the writing circuit to set the first bit line to a low level and the second bit line to a high level.

2. The semiconductor device according to claim 1, further comprises a second transistor for current limiting provided between the plurality of word line driver and the power supply potential,
wherein the control circuit turns off the second transistor based on the reset signal is set to a high level.

3. The semiconductor device according to claim 1,
wherein the control circuit, when the reset signal transitions from high level to low level and all of the plurality of word lines are deselected, controls the precharge circuit so as to start precharging the plurality of pairs of the first bit line and the second bit line.

4. The semiconductor device according to claim 1,
wherein the control circuit includes an internal clock generation circuit for writing and reading, and
wherein the control circuit stops the internal clock generation circuit when the reset signal is at a high level.
